(19) United States
(12) Patent Application Publication
(10) Pub. No.: US 2009/0166826 A1
(43) Pub. Date: Jul. 2, 2009

(54) LEAD FRAME DIE ATTACH PADDLES WITH SLOPED WALLS AND BACKSIDE GROOVES SUITABLE FOR LEADLESS PACKAGES

(76) Inventors: Omar A. Janducayan, Lapu Lapu City (PH); Romolo Bactasa, Singapore (SG); Andrew Abarrientos, Lapu Lapu City (PH)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/965,620

(22) Filed: Dec. 27, 2007

(51) Int. Cl. H01L 21/60; H01L 23/495

(52) U.S. Cl. 257/676; 438/123; 257/E23.04; 257/E21.51

(57) ABSTRACT

Disclosed are die paddle structures for leadframes and methods of attaching die to the die paddles. An exemplary die paddle comprises a sloped wall disposed around an attachment area for a die, where the sloped wall has an obtuse angle of inclination with respect to the attachment area. In one exemplary die-attachment process, solder material is disposed on the attachment area and/or the metalized back surface of a die, the die is placed over the attachment area and substantially within the opening defined by the sloped wall, and the solder is reflowed while the die is allowed to float over the reflowed solder free of external forces from a die-placement tool and to align itself to the sloped wall. Die paddles and attachment methods of the invention reduce the alignment tolerances needed to place the die.

### CROSS-REFERENCES TO RELATED APPLICATIONS

NOT APPLICABLE

### BACKGROUND OF THE INVENTION

A leadframe is a thin layer of patterned metal that connects the electrical pads on the surface of a semiconductor die to the larger electrical terminals of a die package. A leadframe typically comprises a large metal area, called a die paddle, to hold a semiconductor die, and several electrical leads, with the inner ends of the leads disposed about the perimeter of the die paddle. Wire bonds, or the like, electrically couple the inner ends of the leads to the pads of the die. The outer ends of the leads are located away from the die padded and provide the electrical terminals of the package. Typical leadframe have thicknesses between 150 microns and 250 microns, and are made by stamping and/or etching processes. Typically, hundreds of leadframes are manufactured onto a common strip of metal, and are separated from one another after semiconductor dice have been attached to the die paddles and wire bonds have been made. Typically, the strip has various indexing apertures disposed at each leadframe site that enable the strip to be fed into and automatically aligned to the die-attachment and wire-bonding equipment.

A body of plastic material is typically molded around the die paddle and the leads, which may be done before or after the leadframes are separated from the strip. In either case, an outer frame of metal is provided in the leadframe to hold the leads and die paddle in place during the above-described manufacturing steps. Typically, the outer frame is made of the same sheet of metal as the leads and paddle, and is connected to the outer ends of the leads, and connected to the paddle by way of two or more metal bridges. After the package is formed, the leadframe and package are separated from the outer frame.

Efforts have been made to increase the efficiency of each manufacturing step of the leadframe assembly. One current effort is to use die-attachment equipment that simultaneously attaches several semiconductor dice onto several leadframes, rather using equipment that attaches one die at a time. However, as a disadvantage, the multi-die attachment equipment cannot place dice on the leadframes with the same degree of positional accuracy as the single-die attachment equipment, or with the same degree of control over the bond-line thickness (BLT), which is the thickness of the adhesive disposed between the die paddle and leadframe. The loss of accuracy appears to be due a combination of the following factors: movement in the leadframe strip, mechanical play in the equipment (which spans several die positioning tools), and changes in the dimensions of the equipment and the leadframe strip caused by temperature variations. Thus, the practical use of the more efficient multi-die attachment equipment is substantially limited to dice having medium- to large-sized pads, and to leadframes having medium to large dimensions and leads.

### BRIEF SUMMARY OF THE INVENTION

As part of making their invention, the inventors have discovery new die paddle structures that, when coupled with new die-attachment processes, enable the practical use of multi-die attachment equipment on dice having small pads and leadframes having small dimensions and small leads. Broadly stated, a die paddle according to the present invention comprises a sloped wall disposed around an attachment area for a die, where the sloped wall has an obtuse angle of inclination with respect to the attachment area. As one novel die-attachment process, solder material is disposed on the attachment area and/or the metalized back surface of a die, the die is placed over the attachment area and substantially within the opening defined by the sloped wall, and the solder is reflowed while the die is allowed to float over the reflowed solder free of external forces from a die-placement tool (e.g., detached from the die-placement tool). The surface tension and metal-adhesion properties of the reflowed solder bring the floating die into more precise alignment to the sloped wall. As another novel die-attachment process, adhesive material is disposed on the attachment area and/or the back surface of a die, the die is placed over the attachment area and substantially within the opening defined by the sloped wall, and the die is brought into alignment with one or more of the following features: application of light vertical pressure to the die by a pressure plate without substantially restriction the die's horizontal movement relative to the die paddle, application of vibrations to either or both of the die paddle and the pressure plate, and movement of either or both of the die paddle and the pressure plate. Accordingly, die may be attached to die paddle according to the invention using both solder and non-solder material.

In addition to the above advantageous effects, die paddle structures according to the invention may be used to prevent adhesive material, which includes solder and epoxies but not limited thereto, from spreading beyond the defined die attachment area, and thus preventing the adhesive material from interfering with the operation of other components of the leadframe. As a further advantageous effect, the bond line thickness (BLT) of a layer of adhesive material located between the die and the paddle's attachment area may be controlled by disposing a measured amount of adhesive material on the back side of the die and/or on the die attachment area. Controlling the BLT enables the thermal expansion and conductivity characteristics of an assembled package to be better controlled. In further embodiments of the present invention, a die paddle further comprises a groove located in the paddle's back surface and opposite to at least a portion of the sloped wall. When a leadframe having this die paddle is incorporated into a package with the paddle's back surface exposed, the package may be mounted to a circuit board with the paddle's back surface adhered to the board with adhesive material. The groove absorbs excess adhesive material and prevents such material from spreading over the surface of the board and interfering with the operation of other components of the board. Additionally, a groove that is partially or fully filled with adhesive material increases the bonding strength and shear strength of the bond between the package and the board.

These and other embodiments of the invention are described in detail in the Detailed Description with reference to the Figures. In the Figures, like numerals may reference like elements and descriptions of some elements may not be repeated.

### BRIEF DESCRIPTION OF THE DRAWINGS

FIG. 1 shows a perspective top view of an exemplary leadframe embodiment according to the invention.

FIG. 2 shows a cross-sectional view of an exemplary package embodiment according to the invention that uses the exemplary leadframe shown in FIG. 1 according to the invention.

FIG. 3 shows a plan view of the bottom surface of the exemplary package embodiment shown in FIG. 1 according to the invention.

FIG. 4 shows a cross-sectional view of the exemplary package embodiment shown in FIG. 2 as mounted on a board according to the invention.

FIGS. 5 and 6 show cross-sectional views of the exemplary leadframe embodiment shown in FIG. 1 during a first exemplary die-attachment process according to the invention.

FIGS. 7 and 8 show cross-sectional views of the exemplary leadframe embodiment shown in FIG. 1 during a second exemplary die-attachment process according to the invention.

### DETAILED DESCRIPTION OF THE INVENTION

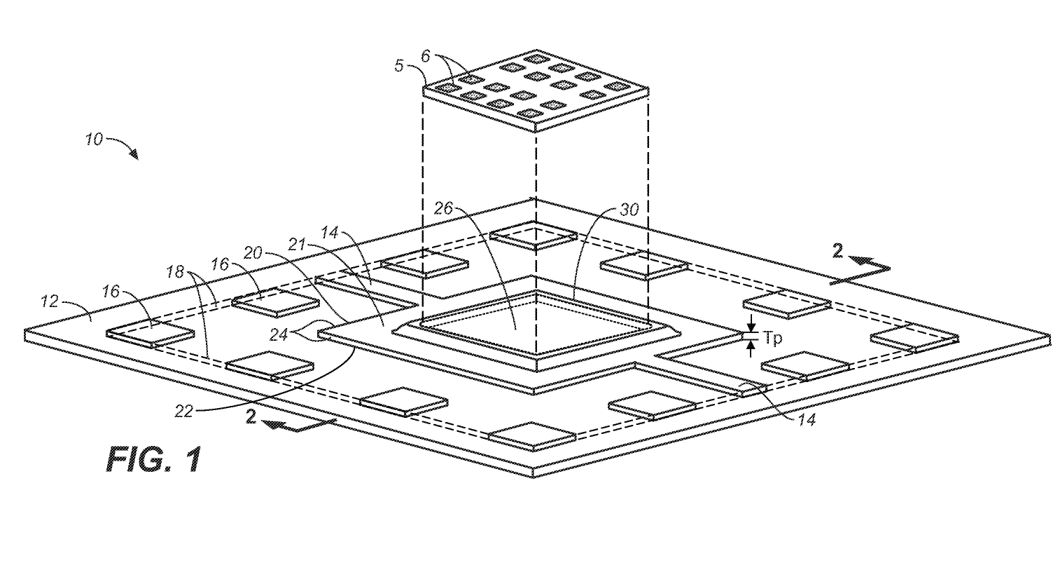

FIG. 1 shows a perspective view of an exemplary embodiment 10 of a leadframe according to the invention for holding a semiconductor die 5 and for making electrical connections to it. Leadframe 10 comprises an outer frame 12, a die paddle 20 attached to frame 12 by bridges 14, and a plurality of conductive regions 16 disposed around die paddle 20 and attached to outer frame 12, all of which are typically metallic. These components may comprises a base layer of copper (Cu) that is coated or alloyed with the following order of metal sub-layers: nickel (Ni), palladium (Pd), and gold (Au). Outer frame 12 and bridges 14 serve to hold the relative positions of die paddle 20 and conductive regions 16 in place during various processing steps of forming a package from leadframe 10 and a semiconductor die. After a package has been formed, outer frame 12 can be separated from conductive regions 16 and bridges 14 along cut planes 18 (shown by dashed lines) by conventional cutting processes. Leadframe 10 may be incorporated into a roll of leadframes (e.g., a hundred or more leadframes arranged in serial form on a strip of conductive material which has been stamped and/or etched to define the features of the frames), which may include various indexing apertures for assisting the transport of the leadframes through processing equipment and for aligning the leadframes to the equipment.

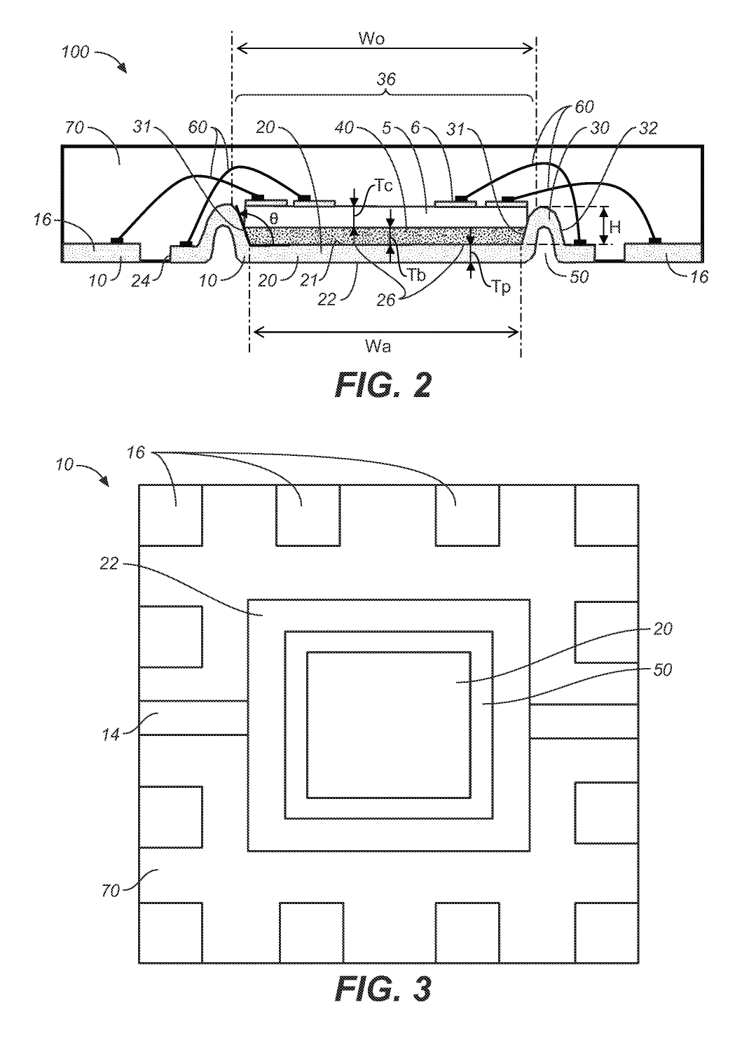

Die paddle 20 has a first surface 21, a second surface 22, a perimeter 24, an attachment area 26 disposed within perimeter 24 to receive semiconductor die 5, and a thickness Tp between surfaces 21 and 22. Typical thicknesses of die paddles range between ˜150 microns (6 mils) and ˜250 microns (10 mils), which are the typical thicknesses of leadframes, and can also be an thin as ˜100 microns (˜4 mils) and as thick as ˜500 microns (20 mils). A sloped wall 31 surrounds attachment area 26. Sloped wall 31 may be provided by a ridge 30 that is formed in first surface 21, with ridge 30 having an inner sloped wall as wall 31, and an outer sloped wall 32. Referring to FIG. 2, sloped wall 31 preferably has an angle of inclination θ with respect to attachment area 26 of more than 90 degrees and less than about 135 degrees, and more preferably in a range that spans from about 95 degrees to about 120 degrees. Sloped wall 31 preferably has a height H with respect to attachment area 26, and defines an opening 36 to attachment area 26 that has a width Wo that is larger than the corresponding width Wa of attachment area 26 (the corresponding widths being along the same dimensional direction). It may be appreciated that sloped wall 31 may be provided by other structures, such as a mesa, raised rim, or raised flange that surrounds attachment area 26, thereby making area 26 into a recess with sloped wall 31 as the recess' wall. It may also be appreciated that two or more of the aforementioned structures (e.g., ridge, mesa, rim, flange) may be used to provide sections of sloped wall 31 (for example, a mesa on one side of area 26, and a ridge on one or more sides of area 26).

FIG. 2 shows a cross-sectional view of an exemplary semiconductor die package 100 according to the invention employing the exemplary die paddle 20 and leadframe 10 shown in FIG. 1. The same reference numbers have been used in this figure (and in subsequent figures) to reference previously-described elements and features. In FIG. 2, the previously-described wall height H, inclination angle θ, and bottom paddle surface 22 can be more clearly seen. In preferred uses of leadframe 10, a layer 40 of adhesive (such as solder) is used to attach die 5 to attachment area 26 with layer 40 having a controlled bond-line thickness (BLT) Tb between die 5 to attachment area 26. The control can be provided by disposing a measured amount of solder material on the backside of die 5 and/or within opening 36, such as in the form of a paste or one or more preformed bodies, placing die 5 over opening 36, applying heat to the solder material to cause it to reflow, and allowing die 5 to float freely over the reflowed solder (e.g., no external pressure applied to the die) at least until the die aligns its sides to the sides of sloped wall 31. At the present time, typical values of bond-line thickness Tb range from about 10 microns (˜0.4 mils) to about 200 microns (8 mils), with values between about 50 microns (2 mils) and about 150 microns (6 mils) being preferred, and values between about 75 microns (3 mils) and about 150 microns being more preferred. Larger amounts of solder, and hence larger BLTs, facility the die's ability to align itself to sloped wall 31 during solder reflow. The solder material may be disposed by any conventional process that enables the quantity to be dispensed in precise amounts, such as solder paste dispensing, ribbon dispensing, and perform dispensing.

For very thin die, which have thicknesses of about 75 microns (3 mils) or less, the height H of sloped wall 31 preferably has a value of 85 microns or more, and more preferably has a value that is within about 20 microns of the combined thicknesses of the die Tc and the desired bond-line thickness Tb (i.e., H=Tc+Tb±20 microns). For a thin die with thickness Tc of 75 microns, this preferred range of H would be ˜65 microns to ˜295 microns for target BLTs in the range of ˜10 microns to ˜200 microns; would be ˜105 microns to ˜245 microns for target BLTs in the range of ˜50 microns to ˜150 microns; and would be ˜130 microns to ˜245 microns for target BLTs in the range of ˜75 microns to ˜150 microns. The relationship H=Tc+Tb±20 microns may be applied to thicker die having thicknesses in the range of 100 microns to 355 microns. Table I provides exemplary ranges of H for sample chip thicknesses and exemplary bond line thickness ranges.

TABLE I

| Wafer | Bond Line Thickness (Tb) Ranges | | |
|---|---|---|---|
| Thickness (Tc) | 25-200 microns | 50-150 microns | 75-150 microns |
| 100 microns | 105-320 microns | 130-270 microns | 155-270 microns |
| 125 microns | 130-345 microns | 155-295 microns | 180-295 microns |
| 200 microns | 205-420 microns | 230-370 microns | 255-370 microns |
| 355 microns | 360-575 microns | 385-525 microns | 410-525 microns |
| 500 microns | 505-720 microns | 530-670 microns | 555-670 microns |

For larger die in the range of 300 microns and above, relationship H=½Tc+Tb±20 microns may be used. Table II provides exemplary ranges of H for sample chip thicknesses and exemplary bond line thickness ranges under this relationship.

TABLE II

| Wafer | Bond Line Thickness (Tb) Ranges | | |
|---|---|---|---|
| Thickness (Tc) | 25-200 microns | 50-150 microns | 75-150 microns |
| 300 microns | 155-370 microns | 180-320 microns | 205-320 microns |
| 355 microns | 182-398 microns | 207-348 microns | 232-348 microns |
| 500 microns | 255-470 microns | 280-420 microns | 305-420 microns |
| 600 microns | 305-520 microns | 330-470 microns | 335-470 microns |

Sloped walls 31 with low heights H are typically formed for thin chips, and are typically made in thin leadframes (˜100 microns to ˜150 microns) since such thin chips usually operate at high speed. As such, the height H is usually more than 50% of the thickness of the leadframe, and typically 65% or more. Sloped walls 31 with heights H of 150 microns or more are typically made in leadframes of moderate thickness (˜250 microns), and thus usually 60% or more of the thickness Tp of the leadframe. Nonetheless. the above values of H given in the text and in Tables I and II may be made in leadframes having common leadframe thicknesses, such 150 microns and 250 microns, with many value of H being equal to or greater than the leadframe thickness. The values for height H as provided in the text and in Tables I and II may be expressed as percentages (rounded to the nearest whole number) relative to the common leadframe thicknesses of 150 microns and 250 microns. For example, H=155 microns may be expresses as 103% of a 150-micron thick leadframe, and as 62% of a 250-micron thick leadframe. Those percentages are incorporated herein by reference so that they may be incorporated into one or more claims of the application at a later date.

In preferred uses of leadframe 10, before die 5 is attached to paddle 20, a controlled amount of adhesive material for layer 40 is disposed on die paddle 20, within opening 36 defined by sloped wall 31, and/or on the back surface of semiconductor die 5. This, in combination with the above-described sloped wall 31 of die paddle 20, provides several advantageous effects. As a first advantageous effect, the height of sloped wall 31 relative to the target bond line thickness and die thickness reduces the chances of the material of layer 40 spreading beyond attachment area 26 and interfering with the operation of conduction regions 16. This enables conductive regions 16 to be more closely spaced to die paddle 20, and enables the creation of a smaller package. As additional advantageous effect, when die 5 has a metalized back surface and solder material is used to provide layer 40, the bond line thickness (BLT) can be controlled to a desired value when die 5 is allowed to float during the solder reflow process. Due to its surface tension and metal adhesion properties, the reflowed solder will spread along the back surface of die 5 and along the top surface of attachment area 26 up to sloped wall 31, and will form a layer between paddle 20 and die 5 that has a substantially even thickness. Thus, a desired bond line thickness can be achieved by disposed a measured amount of solder having a reflowed volume substantially equal to the desired bond line thickness times the area of attachment area 26. As an additional advantageous effect, in the case that die 5 was placed so that a portion of it lies outside of opening 36, the surface tension and adhesion properties of the solder act to pull die 5 completely into opening 36 during the reflow process (with die 5 in a free floating state). This enables leadframe 10 to be used with die assembly equipment having less alignment precision.

Still referring to FIG. 2, after die 5 has been attached to die paddle 20, a plurality of conductive structures 60, such as wire bonds, ribbon bonds, tape-automated bonds (“TAB bonds”), etc., are attached between conductive regions 6 (e.g., pads) on semiconductor die 5 and conductive regions 16 (e.g., leads) of leadframe 10. Conductive structures 60 electrically connect the devices and/or circuitry of die 5 with the terminals (regions 16) of package 100. A body of electrically-insulating molding material 70 is provided over the exposed top surface 21 of leadframe 10, die 5, and conductive structures 60 to provide a sealed package. Material 70 provides mechanical support to conductive structures 60, prevents them from being bent or torn off by external forces, and, along with leadframe 10, provides a rugged shell for semiconductor die package 100. The bottom side 22 of leadframe 10, which includes the bottom sides of conductive regions 16 and die paddle 20, are not covered by material 70 and are left exposed to provide the terminals for the package. Package 100 has a leadless configuration, which means that there are no conductive leads extending substantially beyond the dimensions of the package. Some of conductive structures 60 may be used to electrically couple some conductive regions 6 with die paddle 20 at the paddle's outer edge (between ridge 30 and the periphery of paddle 20). In this case, a ground potential is usually coupled to die paddle 20, which may be done at the bottom surface 22 of die paddle 20.

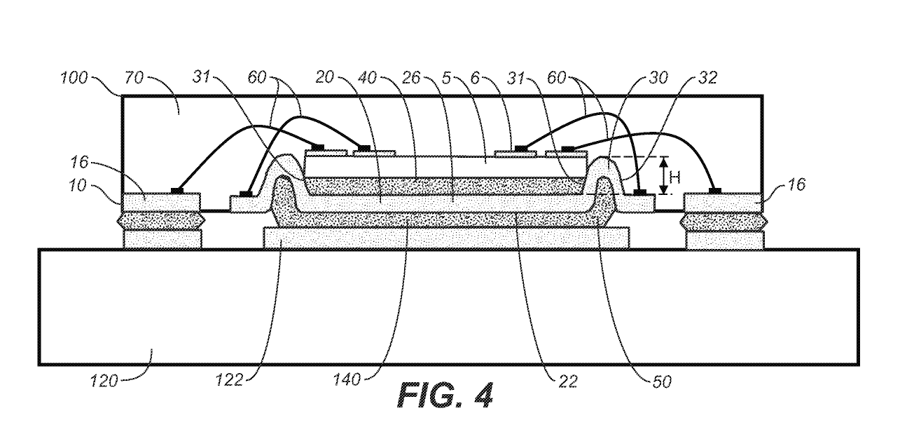

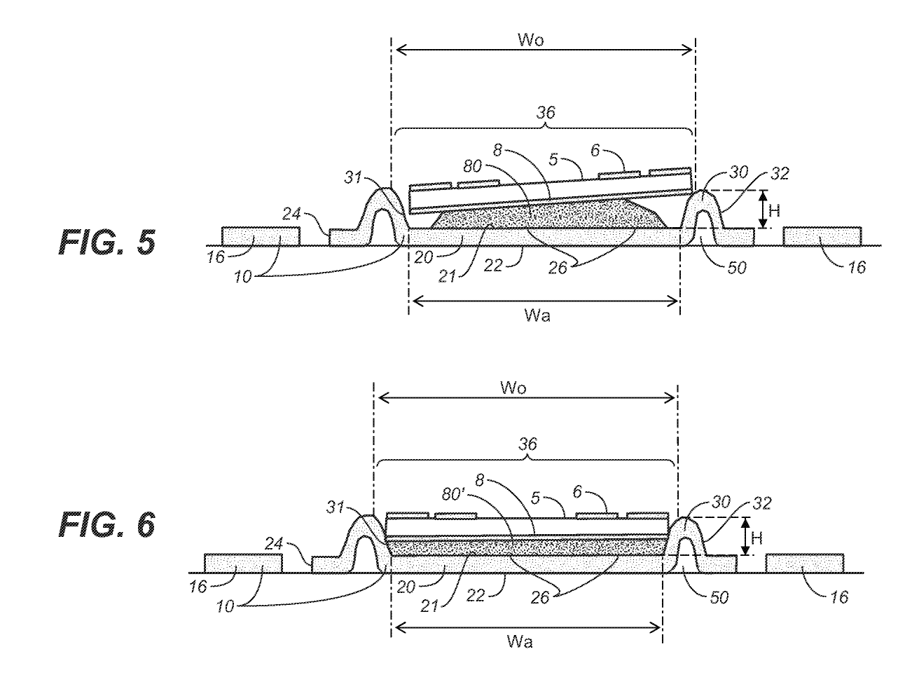

In preferred embodiments, leadframe 10 further comprises a groove 50 disposed on the bottom surface 22 of paddle 20. Groove 50 may be formed opposite to sloped wall 31, and opposite to ridge 30, and may be formed by stamping. Groove 50 is more clearly shown in FIG. 3, which is a bottom plan view of leadframe 10 as incorporated into a package, such as package 100. Groove 50 provides several advantageous effects, as best illustrated in FIG. 4, which is a cross-sectional view of package 100 as mounted to a substrate 120. Substrate 120 may comprise a board, flexible circuit, or the like, may have additional packages attached thereto, and may be comprised by a system or may comprise a complete system along with the packages attached thereto. The back surface 22 of paddle 20 can be attached to a portion of board 120, such as a conductive region 122, by an adhesive material 140, which may comprise solder. Groove 50 provides room for excess adhesive material 140 to flow into, which prevents the material from flashing over to other portions of board 120, such as adjacent conductive regions that are attached to conductive regions 16 of package 100. As an additional benefit, the portion of material 140 that enters groove 50 increases the shear strength against shear forces between package 100 and board 120, including shear forces caused by temperature differences between paddle 20 and board 120. This is because groove 50 provides additional surface area for adhesive material 140 to bond to paddle 20, and because it enables adhesive material 140 to form a rim of material around attachment area 26 that intersects the shear forces (which are parallel to the surface of the package's bottom surface) at a nonparallel angle that ranges between 45 degrees and 90 degrees. The additional surface area also increases bonding strength. The additional surface area provided by groove 50 does not require additional surface area of package 100, thus the shear strength and bonding strength can be increased without increasing the size of package 100.

Semiconductor die 5 may include any suitable semiconductor device. Suitable semiconductor devices may comprise a semiconductor material such as silicon, and may include vertical or horizontal devices. Vertical devices have at least an input at one side of the die and an output at the other side of the die so that current can flow vertically through the die. Horizontal devices include at least one input at one side of the die and at least one output at the same side of the die so that current flows horizontally through the die. In some preferred embodiments of package 100, the semiconductor device in semiconductor die 5 preferably comprises a vertical power transistor. Vertical power transistors include VDMOS transistors and vertical bipolar transistors. A VDMOS transistor is a MOSFET that has two or more semiconductor regions formed by diffusion. It has a source region, a drain region, and a gate. The device is vertical in that the source region and the drain region are at opposite surfaces of the semiconductor die. The gate may be a trenched gate structure or a planar gate structure, and is formed at the same surface as the source region. Trenched gate structures are preferred, since trenched gate structures are narrower and occupy less space than planar gate structures. During operation, the current flow from the source region to the drain region in a VDMOS device is substantially perpendicular to the die surfaces.

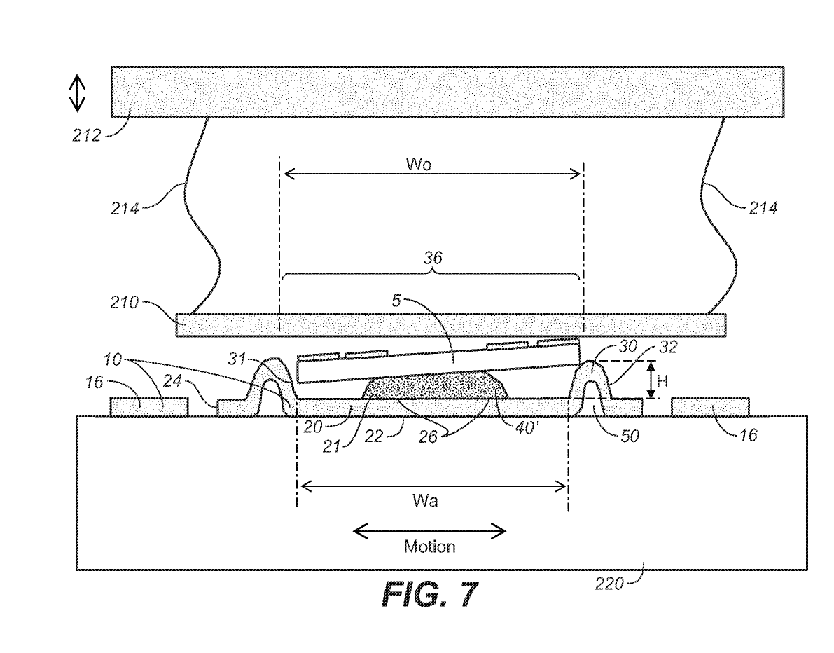

In a first novel die-attachment process according to the present invention, which has been briefly described above, solder material is disposed on attachment area 26 and/or a metalized back surface of a die 5, the die is placed over attachment area 26 and substantially within the opening 36 defined by sloped wall 31. The result of examples of these steps is shown in FIG. 5, where a body of solder 80 in the form of solder paste has been disposed on attachment area 26 and within the opening 36 defined by sloped wall 31, and where a die 5 with a metalized back surface 8 has been placed over the body of solder paste 80, and over area 26 and substantially within the opening 36. As seen in the figure, die 5 is only in rough alignment with sloped wall 31, which may occur even when using the most accurate multi-die attachment equipment, with one edge of the die resting near the top of a portion of sloped wall 31. However, at least a major portion of the die overlies the attachment area. For leadframe embodiment having a sloped wall 31 with a height of 100 microns with respect to attachment area 26 and angle θ of inclination with respect to the attachment area of 120 degrees, opening 36 is approximately 50 microns wider on each side than attachment area 26, which provides for a misalignment tolerance for die 5 of at least ±50 microns in the X-Y plane. Leadframe embodiments having sloped walls 31 of greater height provide proportionally greater tolerances (e.g., H=200 microns provide a tolerance of ±100 microns, etc.). Next, heat is applied to the solder material to place it in a liquid state (i.e., to cause it to reflow, or be in a reflowed state), and semiconductor die 5 is allowed to float on the liquid solder free from external forces applied by a die-placement tool. The surface tension and metal-adhesion properties of the reflowed solder bring the floating die into more precise alignment to the sloped wall. During this time, vibrations may be applied to the die paddle, or the die paddle may be moved in a predetermined motion (e.g., circular, oscillatory, etc.), to speed the alignment process. Next, the solder is allowed to cool to a solid state. The result of these steps is shown in FIG. 6. Because solder paste comprises volatile components such as solvents, flux, and plasticizers, the volume of the reflowed body of solder 80′ shown in FIG. 6 is smaller than the volume of the body of solder paste 80 shown in FIG. 5. Conductive structures 60 may then be attached, and molding material 70 disposed, as previously described.

The dice for a particular semiconductor chip design have variations in their dimensions due to variations in the width of the saws used to cut the dice from the wafers, and due to mechanical play in the sawing equipment. This variation may be denoted by the symbol ±σ. A typical variation ±σ in the widths and lengths of dice is approximately ±26 microns (˜±1 mil). The bond line thickness for the package for a particular semiconductor die having a width W and length L may be selected so that the width at the top of the solder layer, as measured at its intersection with sloped wall 31, is in the range of W±σ and the length in the range of L±σ. Selecting the width and length to be (W+σ) and (L+σ), respectively, may lead to a die misalignment of up to +u in each dimension. Selecting the width and length to be (W−σ) and (L−σ), respectively, could allow the die have substantially perfect alignment in at least one of the dimensions (either width or length) with two of its opposing edges abutting sloped wall 31, with a misalignment of up to ±σ in the other dimension.

The quantity of solder material is preferably dispensed in a measured preset amount to provide a finished solder layer having a reproducible bond line thickness in the range of ˜25 microns to ˜200 microns, and more preferably in the range of ˜50 microns to ˜150 microns, and most preferably in the range of ˜75 microns to ˜150 microns. The solder material may be dispensed by solder paste dispensing, ribbon dispensing, and perform dispensing, and other methods providing measured control. Preferably, the solder material is dispensed so that the bond line thickness of the finished solder layer is within 5 microns of the target thickness when the method is repeated on other instances of the die paddle and a die.

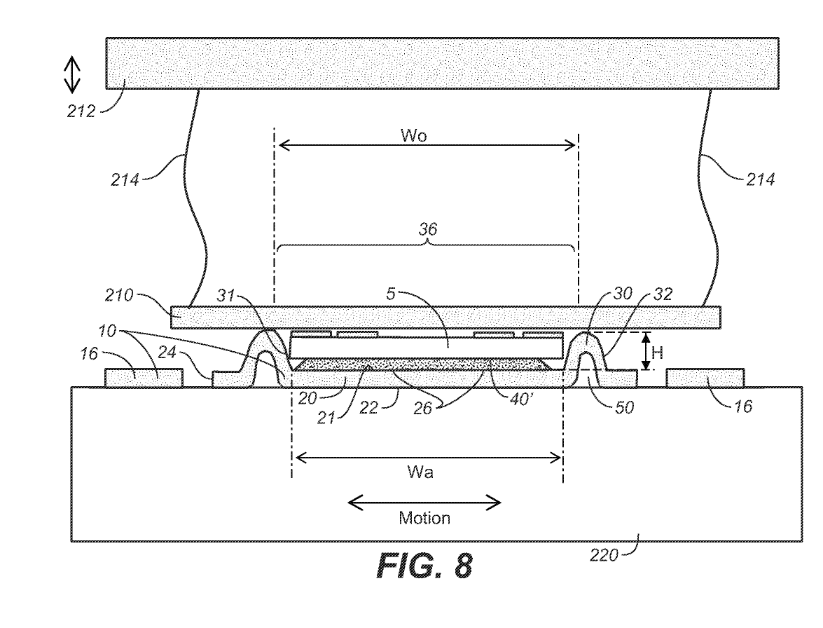

Another novel die-attachment process is shown with reference to FIGS. 7 and 8. A body of adhesive material 90 in a liquid state is disposed on attachment area 26 and/or the back surface of a die 5, the die is placed over attachment area 26 and substantially within the opening 36 defined by sloped wall 31. While in its liquid state, the form of adhesive material 90 may selected such that it has sufficient viscosity and surface adhesion that it may cling to the back of die 5 without dripping off while die 5 is moved into position over attachment area 26. As seen in FIG. 7, die 5 is only in rough alignment with sloped wall 31, with one edge of the die resting near the top of a portion of sloped wall 31, but at least a major portion of the die overlays attachment area 26, with the adhesive material located between the die and the attachment area. In some cases, such as when the liquid adhesive material has a low viscosity and a density greater than that of the die and, die 5 aligns itself to sloped wall 31 shortly after being disposed in opening 36 and before the adhesive material changes to a solid state.

In other cases, the following actions may be preformed while adhesive material 90 is in its liquid state to bring die 5 into alignment with sloped wall 31: (1) applying a force in the direction of gravity to the exposed surface of the die (preferably by a member with a flat surface, such as a plate) without substantially restriction the die's horizontal movement relative to the die paddle, (2) applying vibrations to at least one of the die paddle and the plate, (3) and moving at least one of the die paddle and the plate. The first action can be provided by a small plate 210 (generally with an area less than a square inch) that is lowered over die 5 by a retractable member 212, which is coupled to plate 210 by flexible members 214 (which may comprise strings, flexible wires or chains of 2 or more links). When retractable member 212 is in its raised potion, flexible members 214 are taut and raise plate 210 so that it does not contact die 5. When retractable member 212 is in its lowered potion, flexible members 214 are slack and enable plate 210 to contact die 5, and enable plate 210 and die to move in the horizontal X and Y directions. Plate 210 preferably weighs between 2 grams and 10 grams, and applies a downward force substantially equal to its weight. The second action of applying vibrations may be accomplished by attaching a piezoelectric transducer to plate 210 and driving it with an electric signal, and/or coupling and operating such a transducer to a support member 220 that supports die paddle 20. The third action of moving may be accomplished by moving one or both of retractable member 212 and support member 220, such with a circular motion or an oscillatory motion.

The semiconductor die packages described above can be used in electrical assemblies including circuit boards with the packages mounted thereon. They may also be used in systems such as phones, computers, etc.

Preferred examples described above are directed to “leadless” type packages such as MLP-type packages (microleadframe packages) where the terminal ends of the leads do not extend past the lateral edges of the molding material. Embodiments of the invention may also include leaded packages where the leads extend past the lateral surfaces of the molding material.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly described with respect to the illustrated embodiments, it will be appreciated that various alterations, modifications, adaptations, and equivalent arrangements may be made based on the present disclosure, and are intended to be within the scope of the invention and the appended claims.

What is claimed is:

1. A leadframe for holding a semiconductor die and making electrical connections thereto, the leadframe comprising:
a die paddle having a first surface, a second surface, a perimeter, an attachment area located on the first surface and within the perimeter to receive a semiconductor die, and a first thickness between the first and second surfaces;
a sloped wall disposed in the first surface of the die paddle and surrounding the attachment area, the sloped wall having an angle of inclination with respect to the attachment area of more than 90 degrees; and
a plurality of conductive regions disposed along at least a portion of the perimeter of the die paddle and spaced apart from said perimeter.

2. The leadframe of claim 1 wherein the sloped wall has a height with respect to the attachment area of at least 65 micron.

3. The leadframe of claim 1 wherein the sloped wall has a height with respect to the attachment area of at least 130 microns.

4. The leadframe of claim 1 wherein the sloped wall has a height with respect to the attachment area of at least 155 microns.

5. The leadframe of claim 1 wherein the sloped wall has a height with respect to the attachment area that is greater than 60% of the first thickness.

6. The leadframe of claim 1 further comprising a groove formed in the second surface of the die paddle and opposite to at least a portion of the sloped wall.

7. The leadframe of claim 1 further comprising a ridge disposed in the first surface of the die paddle and surrounding the attachment area, the ridge having an inner wall facing toward the attachment area and an outer wall facing the die paddle perimeter, at least a portion of the sloped wall being coextensive with at least a portion of the sloped wall.

8. The leadframe of claim 7 further comprising a groove formed in the second surface of the die paddle and opposite to at least a portion of the ridge.

9. The leadframe of claim 1 wherein the angle of inclination of the sloped wall is equal to or less than about 135 degrees.

10. The leadframe of claim 1 wherein the angle of inclination of the sloped wall lies in a range that spans from about 95 degrees to about 120 degrees.

11. A semiconductor die package comprising:
a die paddle having a first surface, a second surface, a perimeter, an attachment area located within the perimeter to receive a semiconductor die, and a first thickness between the first and second surfaces;
a sloped wall disposed in the first surface of the die paddle and surrounding the attachment area and defining an opening to the attachment area, the sloped wall having an angle of inclination with respect to the attachment area of more than 90 degrees, the sloped wall having a height with respect to the attachment area of at least 65 microns;
a semiconductor die having a first surface, a second surface, and a second thickness between its surfaces, the semiconductor die being disposed over the attachment area and within the opening; and
an adhesive layer disposed between the second surface of the semiconductor die and the attachment area, the solder layer having a third thickness.

12. The semiconductor die package of claim 11 wherein the sloped wall has a height with respect to the attachment area of at least 130 microns.

13. The semiconductor die package of claim 11 wherein the height of the sloped wall is at least equal to the third thickness plus one-half of the second thickness less 20 microns.

14. The semiconductor die package of claim 11 wherein the height of the sloped wall is at least equal to the third thickness plus the second thickness less 20 microns.

15. The semiconductor die package of claim 11 wherein the adhesive layer comprises solder and has a thickness of at least 50 microns.

16. The semiconductor die package of claim 11 wherein the adhesive layer comprises solder and has a thickness of at least 75 microns.

17. The semiconductor die package of claim 11 further comprising a groove formed in the second surface of the die paddle and opposite to at least a portion of the sloped wall.

18. The semiconductor die package of claim 11 further comprising a ridge disposed in the first surface of the die paddle and surrounding the attachment area, the ridge having an inner wall facing toward the attachment area and an outer wall facing the die paddle perimeter, at least a portion of the sloped wall being coextensive with at least a portion of the sloped wall.

19. The semiconductor die package of claim 18 further comprising a groove formed in the second surface of the die paddle and opposite to at least a portion of the ridge.

20. The leadframe of claim 11 wherein the angle of inclination of the sloped wall is equal to or less than about 135 degrees.

21. The leadframe of claim 11 wherein the angle of inclination of the sloped wall lies in a range that spans from about 95 degrees to about 120 degrees.

22. A system comprising a substrate and the semiconductor die package of claim 11 attached to the substrate.

23. A method of attaching a semiconductor die to a die paddle comprising:
disposing a quantity of solder material on one or both of a surface of a semiconductor die and an attachment area of a die paddle, the attachment area having a first thickness and being substantially surrounded by a sloped wall, the sloped wall having an angle of inclination with respect to the attachment area of more than 90 degrees;
placing the semiconductor die over the attachment area so that at least a major portion of the die overlays the attachment area, and so that solder material is located between the die and the attachment area;
applying heat to the solder material to place it in a liquid state; and
allowing the semiconductor die to float on the solder for at least a portion of the time the solder is in its liquid state.

24. The method of claim 23 further comprising allowing the solder to solidify to form a finished solder layer, and wherein the quantity of solder material is dispensed in a preset amount to provide a finished solder layer having a target thickness in the range of approximately 25 microns to 200 microns.

25. The method of claim 24 wherein the quantity of solder material is dispensed in a preset amount so that the bond line thickness is within 5 microns of the target thickness when the method is repeated with a second instance of the die paddle and a second instance of the die.

26. A method of attaching a semiconductor die to a die paddle comprising:
disposing a quantity of adhesive material in a liquid state on one or both of a surface of a semiconductor die and an attachment area of a die paddle, the attachment area having a first thickness and being substantially surrounded by a sloped wall, the sloped wall having an angle of inclination with respect to the attachment area of more than 90 degrees; and
placing the semiconductor die over the attachment area so that at least a major portion of the die overlays the attachment area, and so that adhesive material is located between the die and the attachment area.

27. The method of claim 26 further comprising: applying a force in the direction of gravity to the exposed surface of the die without substantially restriction the die's horizontal movement relative to the die paddle while the adhesive material is in a liquid state.

28. The method of claim 27 wherein the force is applied by member having a flat surface placed over the die with its flat surface in contact with the die, and wherein the method further comprises at least one of the following:
applying vibrations to at least one of the die paddle and the member;
moving at least one of the die paddle and the member.
